(19) United States
(12) Patent Application Publication
(10) Pub. No.: US 2010/0045297 A1
(43) Pub. Date: Feb. 25, 2010

(54) DEVICE FOR MEASURING THE CURRENT OF A DISCHARGE LAMP

(75) Inventor: Ludger Wilken, Berlin (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/529,206

(22) PCT Filed: Feb. 13, 2008
(86) PCT No.: PCT/EP2008/051709

§ 371 Date: Aug. 31, 2009

(30) Foreign Application Priority Data
Mar. 1, 2007 (DE) 202007003033.9

(51) Int. Cl. G01R 31/00

(52) U.S. Cl. 324/403

(57) ABSTRACT

A device for measuring the current of a discharge lamp, includes a first current measuring device, which converts the current flowing through the lamp into a signal; a second current measuring device, through which a current flows which has the same amplitude response and phase response as the displacement current which flows through the first current measuring device; wherein the signals of the first current measuring device and the second current measuring device are interconnected in such a way that the content of the displacement current in the resultant signal vanishes.

### TECHNICAL FIELD

The invention relates to a device for measuring the current at a discharge lamp, in particular a high-pressure discharge lamp, in particular during the ignition operation and during radiofrequency operation. In order to compensate for the current signal disrupted by a reactive current, a reactive current is produced by a capacitor, which reactive current is converted by a second current measuring device into a voltage, which is subtracted from the current signal.

### PRIOR ART

For current limitation purposes, a discharge lamp L is connected to the power supply system with the voltage UN (for example 240 V) via a ballast BA (FIG. 1). In order to ignite the discharge lamp, ignition gear IG is connected, which ignition gear produces a sequence of high-voltage pulses with amplitudes (for example 5 kV) and short rise times (for example 100 ns). In order to characterize these high-voltage pulses, electrical measurements are carried out, with a high-voltage probe VP (for example Tektronix P6015, divider ratio 1/1000) generally being used for the voltage measurement. A current probe CP (for example Tektronix TCM202) is generally used for the current measurement. The voltage signal U_{U} and the current signal U_{I} are measured and calculated in a suitable manner, for example with an oscilloscope, so as to produce the lamp voltage U_{L}(t) and the current I(t).

FIG. 2 shows, for a 400 W high-pressure sodium-vapor lamp, the voltage U_{L}(t) produced by an ignition gear and the current I(t). Immediately after the rise of the first voltage pulse U_{L}(t), the current signal I(t) rises, although at this time the discharge has not yet been reignited and therefore no lamp current can flow. The measured current is a displacement current I_{D}(t), which is produced by the capacitance which is present between the incoming conductor and the return conductor and is of the order of magnitude of approximately 15 pF and by the large change in voltage at this time.

The displacement current I_{D}(t) is described by

$${I}_{D} ( t ) = {C}_{N} \frac{d {U}_{L} ( t )}{d t} , \qquad ( 1 )$$

where U_{L}(t) is the lamp voltage and is the stray capacitance or coupling capacitance between the high-voltage-carrying conductor and the return conductor. The displacement current I_{D}(t) is subtracted from the measured current signal I(t), which gives the lamp current I_{L}(t):

I_{L}(t)=I(t)−I_{D}(t) (2).

Using a modern oscilloscope, it is possible to calculate the lamp current I_{L}(t) using equation 1 and equation 2. Both the lamp voltage U_{L}(t) and the lamp current I_{L}(t) can therefore be measured directly. The stray capacitance C_{N} is in this case determined by a zero measurement. For this zero measurement, the voltage across the ignition gear is set in such a way that a lamp breakdown cannot take place. The value of the stray capacitance C_{N} is in this case selected such that the lamp current calculated using equation 2 disappears (I_{L}(t)=0).

Electronic ballasts which have relatively high operating frequencies, up to in the MHz range, are used for the operation of discharge lamps. In order to characterize the discharge, the current is also measured with such discharge lamps. Owing to the high operating frequency and the stray capacitances present, a displacement current is superimposed on the measured current. Equation 1 and equation 2 can be used to calculate the lamp current I_{L}(t) from the lamp voltage U_{L}(t) and the stray capacitance C_{N}. As a result of a zero measurement, in the case of which the discharge has not been reignited, the value of the stray capacitance C_{N} is selected such that the resultant lamp current disappears (I_{L}(t)=0).

The stray capacitance in this case comprises the stray capacitance of the lamp C_{L} and the stray capacitance of the line between the current measuring device and the lamp C_{T}.

C_{N}=C_{L}+C_{T} (3)

The stray capacitances C_{L} of the lamps are in the range of from 5 pF to 30 pF. The capacitance C_{T} of the connecting line per unit length is between 50 pF/m and 100 pF/m. Owing to the large changes in voltage (for example 4 kV/μs) or the voltages with high frequencies, the amplitudes of the disruptive displacement currents I_{D}(t) can be of the same order of magnitude (FIG. 2) or even greater than the lamp currents I_{L}(t). In the case of the numerical compensation with equation 1 and equation 2, no longer negligible system faults occur.

### OBJECT

The object of the present invention is to provide a device for measuring the current in discharge lamps whose signal is not disrupted by a displacement current. The way in which this device functions will be explained in more detail using the two exemplary embodiments below.

### DESCRIPTION OF THE INVENTION

The invention proposes providing a fixed device for measuring the lamp current of a discharge lamp. The device contains, inter alia, a measuring transformer for measuring the lamp current and a matched compensation current transformer, which is matched to the measurement setup. The two outputs of the transformers are connected to a measuring amplifier, in which the compensation current is subtracted from the measured current in order to give the real lamp current. The measurement setup can be extended even further such that the lamp voltage is also measured at the same time, and therefore two analog signals for the lamp current and the lamp voltage are available at the output of the arrangement.

### BRIEF DESCRIPTION OF THE DRAWING(S)

FIG. 1 shows voltage and current measurement in the case of a high-pressure discharge lamp in accordance with the prior art with a probe and a current probe, respectively.

FIG. 2 shows an exemplary voltage and current signal with a lamp current calculated therefrom.

FIG. 3 shows the device according to the invention for compensated current measurement on a discharge lamp.

FIG. 4 shows a further embodiment for compensated measurement of the voltage and of the current of a discharge lamp.

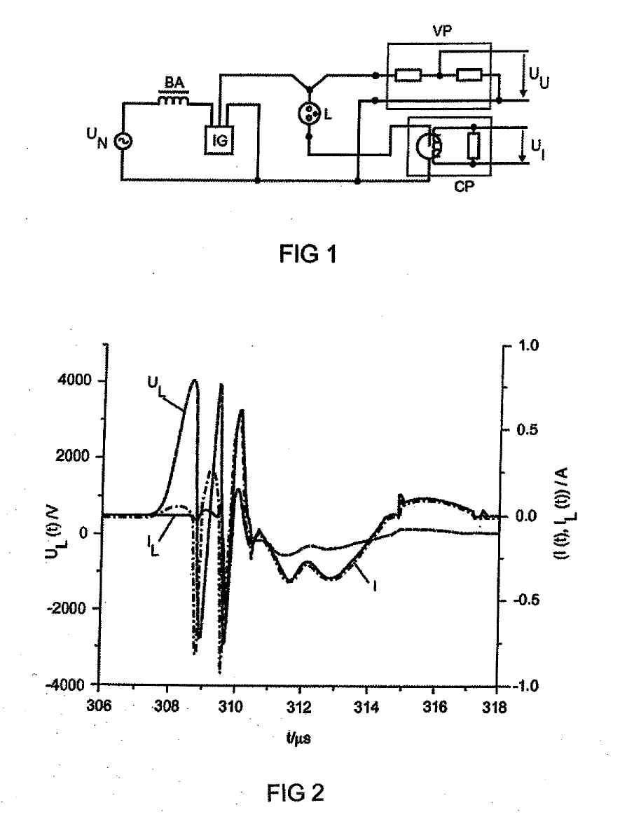

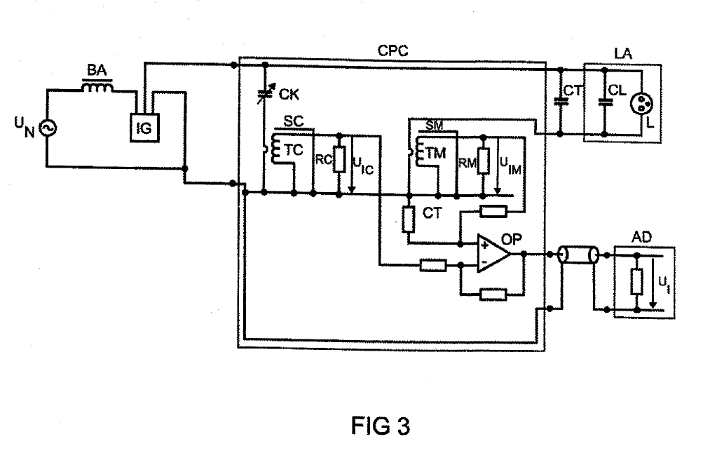

### PREFERRED EMBODIMENT OF THE INVENTION

In FIG. 3, the system voltage U_{N} is connected to the

discharge lamp LA via a ballast BA and ignition gear IG and the measuring device CPC. The current I(t) flowing through the lamp flows through the primary winding of a measuring transformer T_{M}.

This transformer T_{M} can include, on the primary side, a turn or the leadthrough wire and, on the secondary side, a coil with, for example, 15 turns which is wound onto a magnetizable core, for example a ferromagnetic powder toroidal core. In the secondary coil, in accordance with the turns ratio, a current is injected which is converted into a voltage U_{IM} via the resistor R_{M} (for example thick-film resistor, 15Ω), with the result that a current/voltage conversion ratio of 1 V/A is produced, for example. The measuring transformer T_{M} is preferably looped into the return line from the lamp in order to keep the capacitive injection of an interference voltage into the coil low. As a result of a shield SM which is connected to ground, the capacitive injection of an interference voltage into the coil is further reduced.

As a result of the stray capacitance of the lamp C_{L} and the connecting line C_{T}, a capacitive displacement current I_{D}(t) is produced in accordance with equation 1 and equation 3, which displacement current is superimposed on the lamp current I_{L}(t) and the current signal U_{IM}. In order to compensate for the displacement current I_{D}(t), a capacitive displacement current I_{V}(t) is produced by means of the capacitor C_{K}, which can be set, which displacement current flows through the primary winding of the measuring transformer T_{C}. This measuring transformer can include, on the primary side, a turn and, on the secondary side, a coil with a number of turns (for example 15), which coil has been wound onto a magnetizable core (for example ferromagnetic powder toroidal core) and produces a voltage U_{IC} via the resistor R_{C} (for example thick-film resistor, 15Ω). The shield SC produces effective decoupling of the coil with respect to the high-voltage line.

The compensation current transformer should be designed in such a way that it has the same amplitude and phase response as the measuring current transformer. This can be achieved preferably by the selection of identical components. If only a sinusoidal interference voltage is present, for example during radiofrequency operation, the compensation current transformer only needs to have the same phase as the measuring current transformer for the working frequency, as a result of which said compensation current transformer can have a much simpler design.

Using an operational amplifier OP, the current signal U_{IM} and the compensation signal U_{IC} is subtracted and amplified in a suitable manner in order to drive the cable and the terminating resistor. The resultant current signal U_{I} is measured, for example, using an oscilloscope. In the event of a zero measurement without lamp breakdown, the capacitor C_{K} is set in such a way that the current signal disappears (U_{I}=0). The mean value of the capacitor which can be set can be selected in such a way that C_{K}=C_{L}+C_{T}. The setting range is determined by the selected range of the lamp capacitance CL and the length and type of lines between the measuring device and the lampholder. In order to reduce the load capacitance of the measuring device, it is also possible to select the mean value of C_{K} to be lower, for example C_{K}=0.5 (C_{L}+C_{T}) and to amplify or suitably inject the resultant compensation signal U_{IC} in the following circuit.

It is likewise possible to select a fixed capacitor instead of the capacitor which can be set and to match the voltage using an amplifier which can be set. Likewise, it is possible to match the circuit produced by the current transformer with a resistive divider which can be set.

A relatively wide bandwidth can be achieved by the selection of a relatively low current/voltage transformation ratio (for example 0.1 V/A). The following operational amplifier OP can amplify the signal in such a way that, again, the selected current/voltage transformation factor (for example 1 V/A) is provided. Expedient turns numbers for the secondary coil are between 2≦N_{M}≦50 turns, while the resistance values can be in the range 0.01Ω≦R_{M}≦100Ω. Similar figures apply for the compensation current transformer.

With this device it is advantageously possible to measure the lamp current, without a destructive displacement current, during the ignition operation or during radiofrequency operation.

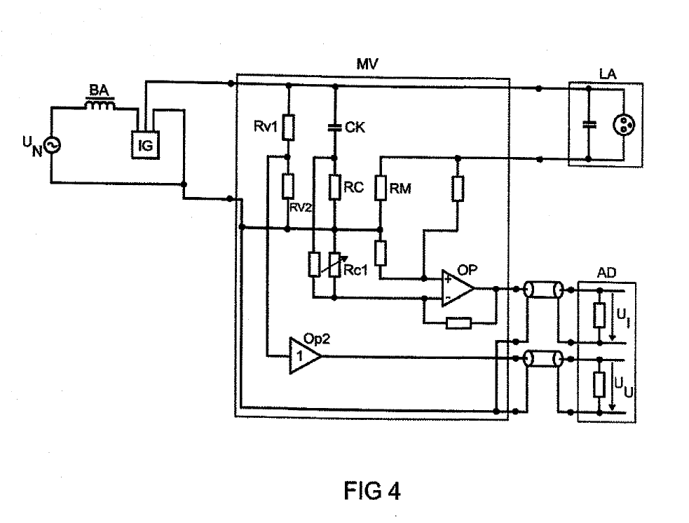

FIG. 4 shows another embodiment of the measuring device. In said figure, now only the resistors R_{M} and R_{C} are used as current-to-voltage converters instead of the transformers T_{M} and T_{C} with the resistors R_{M} and R_{C}. The two resultant voltage signals are subtracted again by the operational amplifier OP and amplified in such a way that the line and the terminating resistor can be driven. The matching of the compensation signal in this case takes place using a resistive divider with the resistor R_{C1} which can be set. The values of the resistors R_{M} and R_{C} are in the range between 0.01Ω and 10Ω.

Generally, in the event of the measurement of the ignition response or during radiofrequency operation, a current signal and a voltage signal are required which have a fixed phase relationship with respect to one another. Advantageously, therefore, a measuring device for voltage measurement is integrated in the measuring device for current measurement. Said measuring device for voltage measurement may include a voltage divider (for example 1/1000), which includes the two resistors R_{V1} and R_{V2}. In order to drive the line and the measuring resistor (for example 50Ω), an impedance converter OP2 can be used.

The device for measuring the current can be integrated in an electronic ballast or electronic ignition gear and produce suitable signals in order to control the ignition and, in particular during radiofrequency operation, the steady state.

The device for measuring the current of a discharge lamp produces the best and most accurate control signals if the disruptive displacement currents of the connecting line are low and the device is fitted in the vicinity of the lamp. During operation of the discharge lamp, the lamp and generally also the lampholder are heated. In order to avoid significant heating of the measuring device which would result in measurement errors, the connecting lines between the lampholders and the connections in the measuring device are selected in terms of length, diameter and material in such a way that the transmitted heat is low. In addition, the measuring device is designed in such a way that a certain amount of heat can also be emitted.

For some applications, it is of interest to integrate the measuring device in the lampholder. In this case, the heating of the measuring device is unavoidable. In order to minimize the measurement errors resulting, a temperature sensor (for example PT100) is additionally incorporated in the measuring device. The measured temperature rise can be used for correcting the amplitude and the phase of the current signal, with a linear temperature phase and temperature amplitude model being used, for example.

1. A device for measuring the current of a discharge lamp, comprising:
a first current measuring device, which converts the current flowing through the lamp into a signal;
a second current measuring device, through which a current flows which has the same amplitude response and phase response as the displacement current which flows through the first current measuring device;
wherein the signals of the first current measuring device and the second current measuring device are interconnected in such a way that the content of the displacement current in the resultant signal vanishes.

2. The device for measuring the current of a discharge lamp as claimed in claim 1, wherein at least one of the first current measuring device and the second current measuring device comprises a low-resistance resistor as current-to-voltage converter.

3. The device for measuring the current of a discharge lamp as claimed in claim 1, wherein at least one of the first current measuring device and the second current measuring device comprises a coil with a terminating resistor as current-to-voltage converter.

4. The device for measuring the current of a discharge lamp as claimed in claim 1, wherein the circuit for matching the voltage of the second current-to-voltage converter comprises a resistive divider.

5. The device for measuring the current of a discharge lamp as claimed in claim 1, wherein the circuit for matching the voltage of the second current-to-voltage converter comprises a voltage-controlled amplifier.

6. The device for measuring the current of a discharge lamp as claimed in claim 1, wherein the circuit for compensating for the reactive current comprises a subtractor or differential amplifier.

7. The device for measuring the current of a discharge lamp as claimed in claim 1, wherein the connecting line to the discharge lamp is configured in terms of length, in terms of thermal conductivity and in terms of diameter such that the heat transmitted by the discharge lamp does not result in a significant increase in temperature at the electronics in the measuring device.

8. The device for measuring the current of a discharge lamp as claimed in claim 1, further comprising a temperature sensor.

9. The device for measuring the current of a discharge lamp as claimed in claim 1, wherein the device for measuring the current of a discharge lamp additionally comprises a device for measuring the lamp voltage.

10. The device for measuring the current of a discharge lamp as claimed in claim 9, wherein the device for voltage measurement comprises a resistive voltage divider.

11. The device for measuring the current of a discharge lamp as claimed in claim 9, wherein the device for transmitting the voltage signal via a cable comprises an impedance converter.

12. The device for electrical measurements on discharge lamps as claimed in claim 1, wherein the device is fitted in the vicinity of the lamp.

13. A lampholder, comprising:
a device for electrical measurements on discharge lamps, comprising:
a first current measuring device, which converts the current flowing through the lamp into a signal;
a second current measuring device, through which a current flows which has the same amplitude response and phase response as the displacement current which flows through the first current measuring device;
wherein the signals of the first current measuring device and the second current measuring device are interconnected in such a way that the content of the displacement current in the resultant signal vanishes.

14. An electronic ballast, comprising:
a device for electrical measurements on discharge lamps, comprising:
a first current measuring device, which converts the current flowing through the lamp into a signal;
a second current measuring device, through which a current flows which has the same amplitude response and phase response as the displacement current which flows through the first current measuring device;
wherein the signals of the first current measuring device and the second current measuring device are interconnected in such a way that the content of the displacement current in the resultant signal vanishes.

15. An ignition gear, comprising:
a device for electrical measurements on discharge lamps, comprising:
a first current measuring device, which converts the current flowing through the lamp into a signal;
a second current measuring device, through which a current flows which has the same amplitude response and phase response as the displacement current which flows through the first current measuring device;
wherein the signals of the first current measuring device and the second current measuring device are interconnected in such a way that the content of the displacement current in the resultant signal vanishes.
